(19) United States
(12) Patent Application Publication
(10) Pub. No.: US 2010/0297796 A1
(43) Pub. Date: Nov. 25, 2010

(54) METHOD FOR MANUFACTURING SEMICONDUCTOR DEVICE

(75) Inventors: Masami Ishiura, Kanagawa (JP); Takuya Fujii, Kanagawa (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: SUMITOMO ELECTRIC DEVICE INNOVATIONS, INC., Yokohama-shi (JP)

(21) Appl. No.: 12/850,241

(22) Filed: Aug. 4, 2010

Related U.S. Application Data
(63) Continuation of application No. PCT/JP2009/051960, filed on Feb. 5, 2009.

(30) Foreign Application Priority Data
Feb. 13, 2008 (JP) 2008-031980

(51) Int. Cl. H01L 21/20

(52) U.S. Cl. 438/31; 257/E21.09

(57) ABSTRACT

A method for manufacturing a semiconductor device including growing an InAlGaAsP layer having a thickness of 1.0 μm or more on a surface of an InP semiconductor layer at a growth temperature of 680 degrees C. or more, a composition ratio “X” of Ga in InAlGa of the InAlGaAsP being 0≦X≦0.08.

### CROSS-REFERENCE TO RELATED APPLICATION

The present application is a continuation of and claims priority to International Patent Application No. PCT/JP2009/051960 filed on Feb. 5, 2009, which claims priority to Japanese Patent Application No. 2008-031980 filed on Feb. 13, 2008, subject matter of these patent documents is incorporated by reference herein in its entirety.

### BACKGROUND

(i) Technical Field

A certain aspect of the embodiments discussed herein is related to a method for manufacturing a semiconductor device.

(ii) Related Art

It is necessary to control a temperature of an optical waveguide in order to control an oscillation wavelength of a communication semiconductor laser used in a DWDM (Dense Wavelength Division Multiplexing) system. Conventionally, a temperature control device (TEC) controls a temperature of a laser chip mounted on a carrier. In this case, however, large electrical power is required, because it is necessary to control a temperature of the carrier having large heat capacity.

And so, it is supposed that a resistive element is provided on a surface of the laser chip. Further, Japanese Patent Application Publication No. 2007-273644 (hereinafter referred to as Document 1) discloses an art where a mesa for thermal separation is formed and a thermal resistive crystal is inserted under the mesa in order to reduce electrical power consumption. The thermal resistive crystal may be a quaternary mixed crystal lattice-matched to InP and may have a thickness of 1 μm or more. It is preferable that the thermal resistive crystal has a large band gap. This is because an influence on a light transmitting in the optical waveguide is restrained.

InAlAsP may be used as the thermal resistive crystal. Japanese Patent Application Publication No. 2000-216500 (hereinafter referred to as Document 2) discloses a semiconductor element having InAlAsP. Here, the semiconductor layer made of InAlAsP is grown at relatively low temperature (500 degrees C.). This is because phosphorus may be volatile when the InAlAsP is grown at high temperature.

The inventors review further improvement of semiconductor device property with use of an InAlAsP-based semiconductor layer. In accordance with a review of the inventors, relatively large convexo-concave appears on a surface of InAlAsP-based semiconductor layer when the InAlAsP having a thickness of 1 μm or more is grown. If the convexo-concave is reduced, the semiconductor device property may be improved.

### SUMMARY

According to an aspect of the present invention, there is provided a method for manufacturing a semiconductor device including growing an InAlGaAsP layer having a thickness of 1.0 μm or more on a surface of an InP semiconductor layer at a growth temperature of 680 degrees C. or more, a composition ratio “X” of Ga in InAlGa of the InAlGaAsP being 0≦X≦0.08.

### BRIEF DESCRIPTION OF THE DRAWINGS

FIG. 1A through FIG. 1E illustrate a method of manufacturing a semiconductor device in accordance with a first embodiment of the present invention;

FIG. 2 illustrates a schematic cross sectional view of an optical component in accordance with a second embodiment;

FIG. 3 illustrates a perspective view of an overall structure of a semiconductor laser chip in accordance with a third embodiment;

FIG. 4A illustrates a plane view of the semiconductor laser chip;

FIG. 4B illustrates a cross sectional view taken along a line A-A of FIG. 4A;

FIG. 5A and FIG. 5B illustrate a picture of an observed image;

FIG. 6A through FIG. 6D illustrate a picture of an observed image;

FIG. 7A through FIG. 7D illustrate a picture of an observed image; and

FIG. 8A through FIG. 8D illustrate a picture of an observed image.

### DETAILED DESCRIPTION

A description will be given of a best mode for carrying the present invention.

### First Embodiment

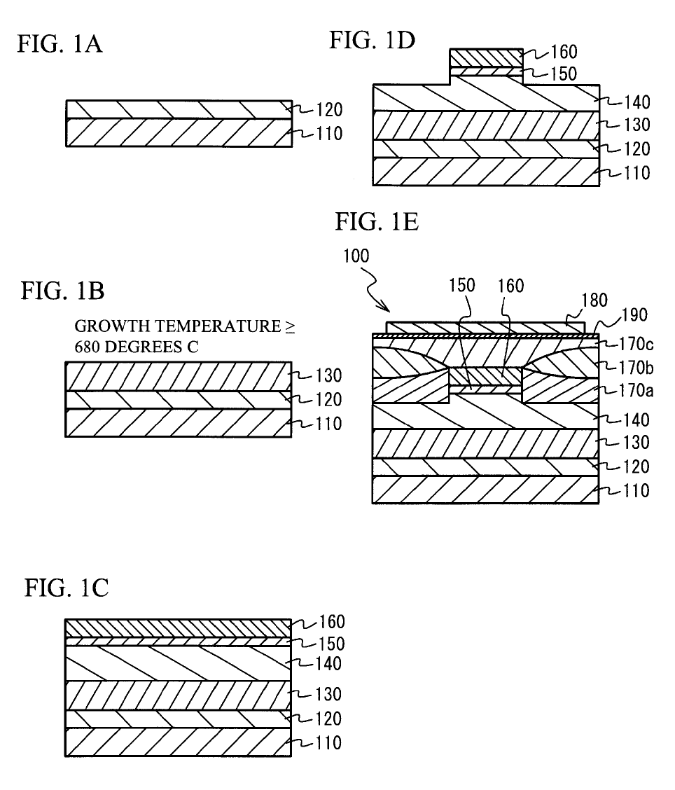

FIG. 1A through FIG. 1E illustrate a method of manufacturing a semiconductor device 100 in accordance with a first embodiment of the present invention. In FIG. 1A through FIG. 1E, a schematic cross sectional view is illustrated. As illustrated in FIG. 1A, a buffer layer 120 made of n-type InP is grown on a semiconductor substrate 110 made of n-type InP (coupling face is {100}). In concrete, the semiconductor substrate 110 is heated. And, the buffer layer 120 having a thickness of approximately 0.1 μm is grown at a growth temperature of 630 degrees C. The growth temperature is a substrate temperature when growing a layer. Therefore, the growth temperature is a temperature of the semiconductor substrate 110 in a process of FIG. 1A.

Next, as illustrated in FIG. 1B, a low-thermal-conductivity layer 130 having a thickness of 1.0 μm or more is grown on the buffer layer 120 in an atmosphere of 50 Torr to 150 Torr at a growth temperature of 680 degrees C. or more. The low-thermal-conductivity layer 130 is a semiconductor layer having a thermal conductivity lower than the buffer layer 120 and a cladding layer 140 described later and is made of InAlAsP.

Then, as illustrated in FIG. 1C, the cladding layer 140 having a thickness of approximately 1.0 μm, an optical waveguide layer 150 having a thickness of approximately 0.3 μm and a cladding layer 160 having a thickness of approximately 0.3 μm are grown on the low-thermal-conductivity layer 130 at a growth temperature of 630 degrees C. The cladding layer 140 is made of n-type InP. The optical waveguide layer 150 is made of i-type InGaAsP. The cladding layer 160 is made of p-type InP.

Next, as illustrated in FIG. 1D, an oxide film mask (not shown) is formed on the cladding layer 160 with coating and exposing of resist. The cladding layer 160, the optical waveguide layer 150 and the cladding layer 140 are subjected to an etching process. Thus, a strip mesa made of the cladding layer 160 and the optical waveguide layer 150 is formed.

Then, as illustrated in FIG. 1E, an implanting layer 170a made of p-type InP and an implanting layer 170b made of n-type InP are grown on both sides of the stripe mesa. Then, an implanting layer 170c made of p-type InP is grown so as to implant the implanting layer 170a, the implanting layer 170b and the cladding layer 160. After that, an insulating layer 190 is formed on the implanting layer 170c. A heater 180 such as a thin film resistor is provided on the insulating layer 190. With the processes, the semiconductor device 100 is fabricated.

In the growing processes, a MOCVD method may be used. Tri-methyl-indium (TMI), tri-methyl-aluminum (TMAl), arsine (AsH₃) and phosphine (PH₃) are used as gas source.

It is preferable that a composition ratio “Y” of Al in InAl in InAlAsP is 0.09≦Y≦0.37. It is preferable that a composition ratio “Z” of P in AsP in InAlAsP is 0.20≦Z≦0.80. In this case, convexo-concave formation of the low-thermal-conductivity layer 130 is restrained effectively.

The low-thermal-conductivity layer 130 may be made of InAlGaAsP (composition ratio “X” of Ga is 0≦X≦0.08). In this case, it is possible to form the high quality low-thermal-conductivity layer 130 having a thickness of 1.0 μm or more at a growth temperature of 680 degrees C. or more. It is necessary to enlarge a band gap at the low-thermal-conductivity layer 130 in order to reduce influence on the optical waveguide layer 150. And so, in the embodiment, a composition ratio “X” of Ga in InAlGa is X≦0.08. InAsGaAsP can be grown with a MOCVD method with use of gas source of tri-methyl-gallium (TEG), tri-methyl-indium (TMI), tri-methyl-aluminum (TMAl), arsine (AsH₃) and phosphine (PH₃).

It is preferable that an interval between the optical waveguide layer 150 and the low-thermal-conductivity layer 130 is 1 μm or more. If the interval between the optical waveguide layer 150 and the low-thermal-conductivity layer 130 is small, a light transmitting in InAlAsP is increased. This results in bad influence on transmittance property of the optical waveguide layer 150.

It is preferable that an etch pit density (EPD) at a surface of the semiconductor substrate 110 is 2000/cm² or less. This is because convexo-concave formation at the surface is restrained when there are a few defects in the substrate, and the high quality low-thermal-conductivity layer 130 can be grown.

It is preferable that a coupling face of the semiconductor substrate 110 is {100} face plus minus 0.08 degrees. This is because the convexo-concave formation at the surface is restrained and the high quality low-thermal-conductivity layer 130 may be grown when the substrate face has an approximately flat surface.

### Second Embodiment

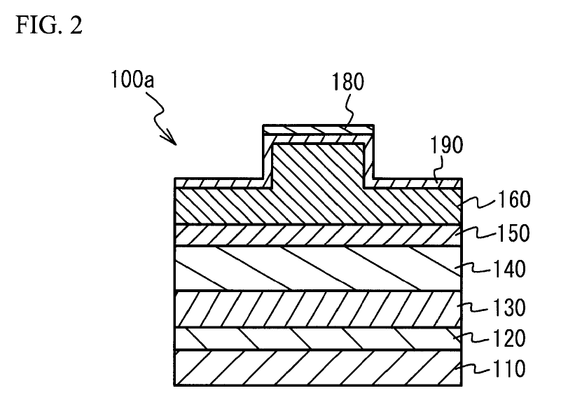

Next, a description will be given of a semiconductor device 100a in accordance with a second embodiment. FIG. 2 illustrates a schematic cross sectional view of the semiconductor device 100a. As illustrated in FIG. 2, the semiconductor device 100a has a structure in which the buffer layer 120, the low-thermal-conductivity layer 130, the cladding layer 140, the optical waveguide layer 150 and the cladding layer 160 are grown in order on the semiconductor substrate 110. The cladding layer 160 has a convex portion in a center area of an upper face thereof. The convex portion has a stripe shape extending in a longitudinal direction of the optical waveguide layer 150. The insulating layer 190 is provided on the cladding layer 160. The heater 180 is provided on the insulating layer 190 above the convex portion of the cladding layer 160.

The low-thermal-conductivity layer 130 is grown with the method as illustrated in FIG. 1B in the first embodiment. This allows a formation of the high quality low-thermal-conductivity layer 130 where the convexo-concave formation is restrained.

### Third Embodiment

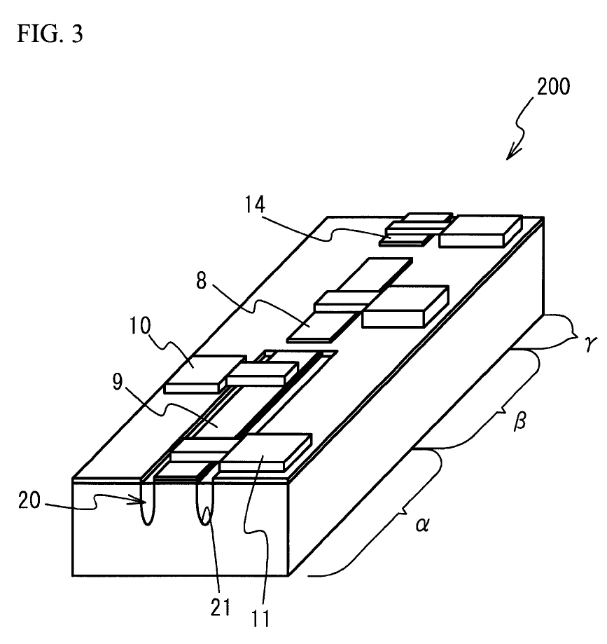

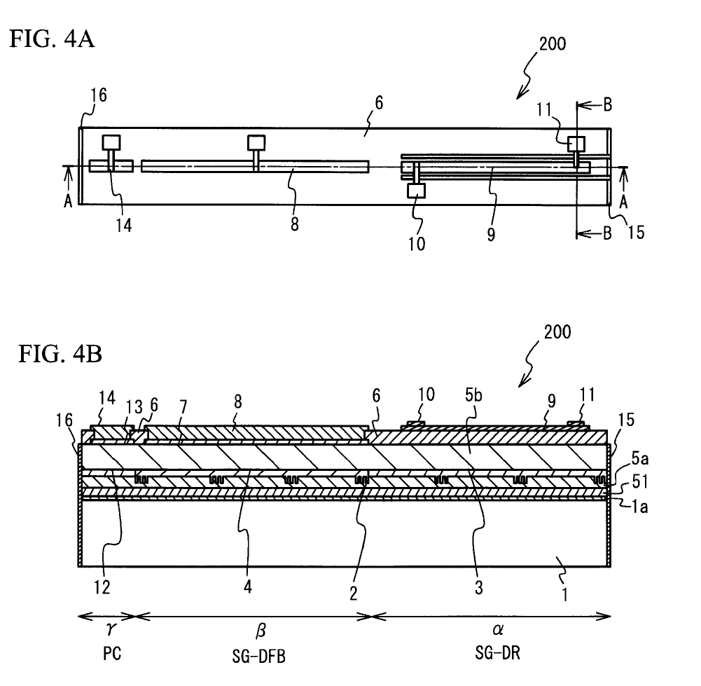

Next, a description will be given of a semiconductor laser chip 200 in accordance with a third embodiment. The semiconductor laser chip 200 includes the semiconductor device 100 in accordance with the first embodiment. FIG. 3 illustrates a perspective view of an overall structure of the semiconductor laser chip 200. FIG. 4A illustrates a plane view of the semiconductor laser chip 200. FIG. 4B illustrates a cross sectional view taken along a line A-A of FIG. 4A. A description will be given of the semiconductor laser chip 200 with reference to FIG. 3, FIG. 4A and FIG. 4B.

As illustrated in FIG. 3, FIG. 4A and FIG. 4B, the semiconductor laser chip 200 has a structure in which a SG-DR (Sampled Grating Distributed Reflector) region α, a SG-DFB (Sampled Grating Distributed Feedback) region β and a PC (Power Control) region γ are coupled in order.

The SG-DR region α has a structure in which a buffer layer 1a, a low-thermal-conductivity layer 51, a lower cladding layer 5a, an optical waveguide layer 3, an upper cladding layer 5b and an insulating layer 6 are provided on a semiconductor substrate 1 in order, and a heater 9, a power electrode 10 and a ground electrode 11 are provided on the insulating layer 6. The SG-DFB region β has a structure in which the buffer layer 1a, the low-thermal-conductivity layer 51, the lower cladding layer 5a, an optical waveguide layer 4, the upper cladding layer 5b, a contact layer 7 and an electrode 8 are provided on the semiconductor substrate 1 in order. The PC region γ has a structure in which the buffer layer 1a, the low-thermal-conductivity layer 51, the lower cladding layer 5a, an optical waveguide layer 12, the upper cladding layer 5b, a contact layer 13 and an electrode 14 are provided on the semiconductor substrate 1 in order.

The semiconductor substrate 1, the buffer layer 1a, the low-thermal-conductivity layer 51, the lower cladding layer 5a and the upper cladding layer 5b of the SG-DR region α, the SG-DFB region β and the PC region γ are respectively a single layer formed integrally. The optical waveguide layers 3, 4 and 12 are formed on the same plane and are optically coupled.

A low reflection film 15 is formed on an edge face of the semiconductor substrate 1, the buffer layer 1a, the low-thermal-conductivity layer 51, the optical waveguide layer 3, the lower cladding layer 5a and the upper cladding layer 5b on the SG-DR region a side. On the other hand, a low reflection film 16 is formed on an edge face of the semiconductor substrate 1, the optical waveguide layer 12, the lower cladding layer 5a and the upper cladding layer 5b on the PC region γ side. A plurality of diffractive gratings 2 are formed in the optical waveguide layers 3 and 4 at a given interval. Thus, a sampled grating is formed. The insulating layer 6 is also formed between the electrode 8 and the electrode 14.

The semiconductor substrate 1 and the buffer layer 1a are, for example, made of InP. The optical waveguide layer 3 is, for example, made of InGaAsP-based crystal having an absorption edge shorter than a laser oscillation wavelength and has a PL wavelength of approximately 1.3 μm. The optical waveguide layer 4 includes an active layer made of InGaAsP-based crystal having a gain with respect to the laser oscillation at a desirable wavelength and has a PL wavelength of approximately 1.57 μm. The optical waveguide layer 12 is made of InGaAsP-based crystal for changing an intensity of emitted light by absorbing or amplifying a light, and has a PL wavelength of approximately 1.57 μm.

The optical waveguide layer 3 has a plurality of SG-DR segments. In the embodiment, the optical waveguide layer 3 has three SG-DR segments. Here, the SG-DR segment is a region in which a single region having the diffractive grating 2 and a single space region not having the diffractive grating 2 are connected in the optical waveguide layer 3.

The lower cladding layer 5a and the upper cladding layer 5b are, for example, made of InP and confine a laser light transmitting in the optical waveguide layers 3, 4 and 12. The low-thermal-conductivity layer 51 is provided under the lower cladding layer 5a. The low-thermal-conductivity layer 51 is made of a material having a thermal conductivity smaller than that of the lower cladding layer 5a. The low-thermal-conductivity layer 51 is made of the same material as the low-thermal-conductivity layer 130 of the first embodiment (InAlAsP or InAlGaAsP). The contact layers 7 and 13 are made of InGaAsP-based crystal. The insulating layer 6 is a protective layer made of an insulating material such as SiN or SiO₂. The low reflection films 15 and 16 are, for example, made of a dielectric material including MgF₂ and TiON and have a reflection rate of 0.3% or less.

The heater 9 is made of NiCr or the like and is provided on the insulating layer 6. The heater 9 is coupled to the power electrode 10 and the ground electrode 11. The power electrode 10, the ground electrode 11 and the electrodes 8 and 14 are made of conductive material such as Au. As illustrated in FIG. 3, a mesa groove 21 is formed from both sides of the heater 9 to the semiconductor substrate 1 through both sides of the optical waveguide layer 3 in parallel with the optical waveguide layer 3. In the embodiment, a mesa semiconductor region 20 demarcated with the mesa groove 21 and including the optical waveguide layer 3 acts as the semiconductor device 100.

Next, a description will be given of an operation of the semiconductor laser chip 200. The optical waveguide layer 4 generates a light when a given current is provided to the electrode 8. The generated light transmits in the optical waveguide layers 3 and 4 and is repeatedly reflected and amplified. This allows a laser oscillation. A part of the generated laser light is amplified or absorbed in the optical waveguide layer 12, and is emitted outside through the low reflection film 16. It is possible to control an amplification factor or an absorption factor of the optical waveguide layer 12 with a current provided to the electrode 14. The intensity of the emitted light is kept constant when a predetermined current is provided to the electrode 14.

Each temperature of the SG-DR segments are controlled according to a current provided to the heater 9. Accordingly, the refractive index of each SG-DR segment changes. This results in a changing of a reflection peak wavelength of the optical waveguide layer 3. It is therefore possible to control the oscillation wavelength of the semiconductor laser chip 200 by controlling the current provided to the heater 9.

In the embodiment, a thermal resistance is enlarged between the optical waveguide layer 3 and the semiconductor substrate 1 because the low-thermal-conductivity layer 51 is provided under the lower cladding layer 5a. Therefore, heat influence from the semiconductor substrate 1 is reduced, and it is possible to control the temperature of the optical waveguide layer 3 effectively with the heat of the heater 9. Accordingly, the control of the oscillation wavelength of the semiconductor laser chip 200 is improved. The low-thermal-conductivity layer 51 may be formed only in the SG-DR region α.

The semiconductor substrate 1 corresponds to the semiconductor substrate 110, the buffer layer 1a corresponds to the buffer layer 120, the lower cladding layer 5a corresponds to the cladding layer 140, the low-thermal conductivity layer 51 corresponds to the low-thermal-conductivity layer 130, the optical waveguide layer 3 corresponds to the optical waveguide layer 150, the upper cladding layer 5b corresponds to the cladding layer 160, and the heater 9 corresponds to the heater 180, in a relation between the third embodiment and the first embodiment.

### EXAMPLES

The low-thermal-conductivity layer in accordance with the above-mentioned embodiment is grown, and the property of the low-thermal-conductivity layer is measured.

### Example 1

In an example 1, In_{0.76}Al_{0.24}As_{0.50}P_{0.50} layer of 1.0 μm was grown on an InP layer at a growth temperature of 680 degrees C.

### Example 2

In an example 2, In_{0.76}Al_{0.24}As_{0.50}P_{0.50} layer of 1.5 μm was grown on an InP layer at a growth temperature of 680 degrees C.

### Example 3

In an example 3, In_{0.76}Al_{0.24}As_{0.50}P_{0.50} layer of 1.8 μm was grown on an InP layer at a growth temperature of 680 degrees C.

### Example 4

In an example 4, In_{0.76}Al_{0.24}As_{0.50}P_{0.50} layer of 2.0 μm was grown on an InP layer at a growth temperature of 680 degrees C.

### Example 5

In an example 5, In_{0.76}Al_{0.24}As_{0.50}P_{0.50} layer of 2.0 μm was grown on an InP layer at a growth temperature of 700 degrees C.

### Example 6

In an example 6, In_{0.76}Al_{0.24}As_{0.50}P_{0.50} layer of 2.0 μm was grown on an InP layer at a growth temperature of 730 degrees C.

### Example 7

In an example 7, In_{0.76}Al_{0.24}As_{0.50}P_{0.50} layer of 2.0 μm was grown on an InP layer at a growth temperature of 750 degrees C.

### Example 8

In an example 8, In_{0.91}Al_{0.09}As_{0.20}P_{0.80} layer of 1.0 μm was grown on an InP layer at a growth temperature of 680 degrees C.

### Example 9

In an example 9, In_{0.63}Al_{0.37}As_{0.80}P_{0.2} of 1.0 μm was grown on an InP layer at a growth temperature of 680 degrees C.

### Example 10

In an example 10, In_{0.80}Al_{0.20}As_{0.50}P_{0.50} layer of 1.5 μm was grown on an InP layer ({100} face+0.08 degrees) at a growth temperature of 680 degrees C.

### Example 11

In an example 11, In_{0.80}Al_{0.20}As_{0.50}P_{0.50} of 1.5 μm was grown on an InP layer ({100} face−0.08 degrees) at a growth temperature of 700 degrees C.

### Example 12

In an example 12, In_{0.76}Ga_{0.08}Al_{0.16}As_{0.50}P_{0.50} layer of 2.0 μm was grown on an InP layer at a growth temperature of 680 degrees C.

### Comparative Example 1

In a comparative example 1, In_{0.76}Al_{0.24}As_{0.50}P_{0.50} layer of 0.5 μm was grown on an InP layer at a growth temperature of 630 degrees C.

### Comparative Example 2

In a comparative example 2, In_{0.76}Al_{0.24}As_{0.50}P_{0.50} layer of 1.0 μm was grown on an InP layer at a growth temperature of 630 degrees C.

Table shows the growth temperature and thickness of the InGaAlAsP layer of the examples 1 to 12 and the comparative examples 1 and 2.

TABLE 1

| | | GROWTH | GROWTH |
|---|---|---|---|
| | | TEM- | THICK- |
| | COMPOSITION RATIO | PERATURE | NESS |
| EXAMPLE 1 | In_{0.76}Al_{0.24}As_{0.50}P_{0.50} | 680° C. | 1.0 μm |
| EXAMPLE 2 | In_{0.76}Al_{0.24}As_{0.50}P_{0.50} | 680° C. | 1.5 μm |
| EXAMPLE 3 | In_{0.76}Al_{0.24}As_{0.50}P_{0.50} | 680° C. | 1.8 μm |
| EXAMPLE 4 | In_{0.76}Al_{0.24}As_{0.50}P_{0.50} | 680° C. | 2.0 μm |
| EXAMPLE 5 | In_{0.76}Al_{0.24}As_{0.50}P_{0.50} | 700° C. | 2.0 μm |
| EXAMPLE 6 | In_{0.76}Al_{0.24}As_{0.50}P_{0.50} | 730° C. | 2.0 μm |
| EXAMPLE 7 | In_{0.76}Al_{0.24}As_{0.50}P_{0.50} | 750° C. | 2.0 μm |
| EXAMPLE 8 | In_{0.91}Al_{0.09}As_{0.20}P_{0.80} | 680° C. | 1.0 μm |
| EXAMPLE 9 | In_{0.63}Al_{0.37}As_{0.80}P_{0.20} | 680° C. | 1.0 μm |
| EXAMPLE 10 | In_{0.80}Al_{0.20}As_{0.50}P_{0.50} | 680° C. | 1.5 μm |
| EXAMPLE 11 | In_{0.80}Al_{0.20}As_{0.50}P_{0.50} | 680° C. | 1.5 μm |
| EXAMPLE 12 | In_{0.76}Ga_{0.08}Al_{0.16}As_{0.50}P_{0.50} | 680° C. | 2.0 μm |
| COMPARATIVE | In_{0.76}Al_{0.24}As_{0.50}P_{0.50} | 630° C. | 0.5 μm |
| EXAMPLE 1 | | | |
| COMPARATIVE | In_{0.76}Al_{0.24}As_{0.50}P_{0.50} | 630° C. | 1.0 μm |
| EXAMPLE 2 | | | |

An InP layer of 2.0 μm was further grown on the low-thermal-conductivity layers of the examples 1 to 12 and the comparative examples 1 and 2, because a surface of a quaternary layer such as InAlAsP is liable to variation.

### (Analysis)

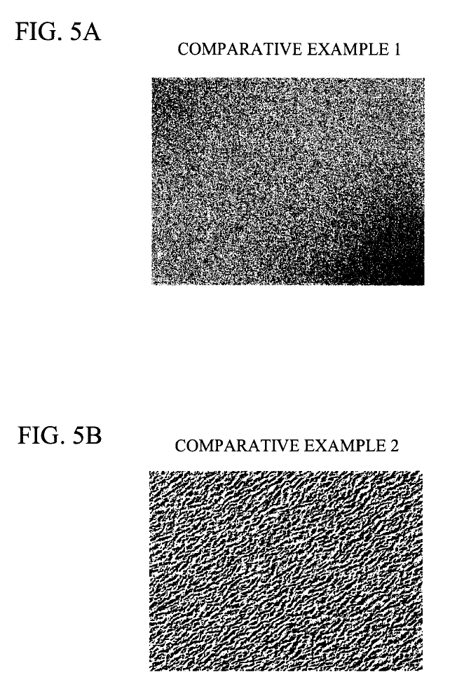

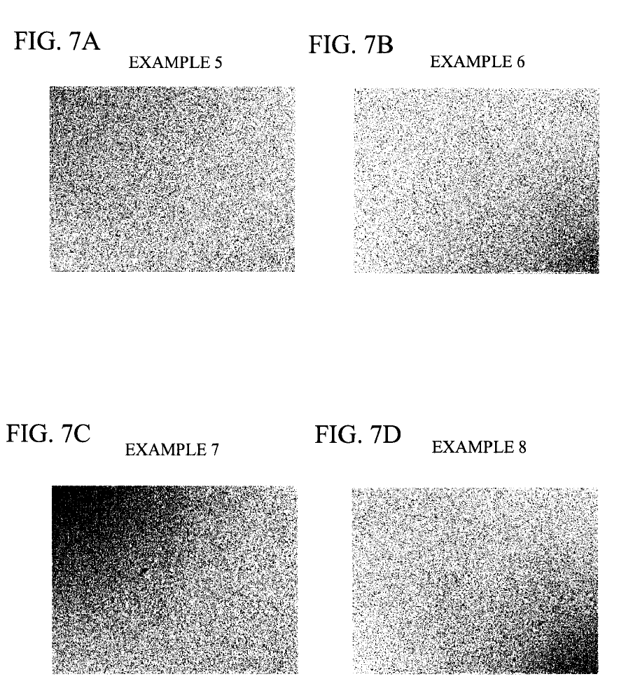

The surfaces of The InGaAlAsP layer and the InAlAsP layer of the examples 1 to 12 and the comparative examples 1 and 2 were observed with a differential interference microscope. FIG. 5A to FIG. 8D are a picture of an observed image. In the picture of FIG. 5A to FIG. 8D, the more even contrasting density distribution is, the flatter the surface is.

In the comparative example 1, the growth temperature of the InAlAsP layer was 630 degrees C. The growth temperature of InP adopted in an InP-based device frequently is adopted in the comparative example 1, although Document 2 discloses a growth temperature of 500 degrees C. In the comparative example 1, the thickness of the InAlAsP layer was 0.5 μm. In the comparative example 1, convexo-concave was not observed on a surface of the InAlAsP layer, as illustrated in FIG. 5A.

On the other hand, in the comparative example 2, the thickness of the InAlAsP layer was 1.0 μm. In the comparative example 2, convexo-concave was observed on the surface of the InAlAsP layer, as illustrated in FIG. 5B. Therefore, it may be understood that the convexo-concave appears on the surface of the InAlAsP layer when the thickness of the InAlAsP layer is enlarged.

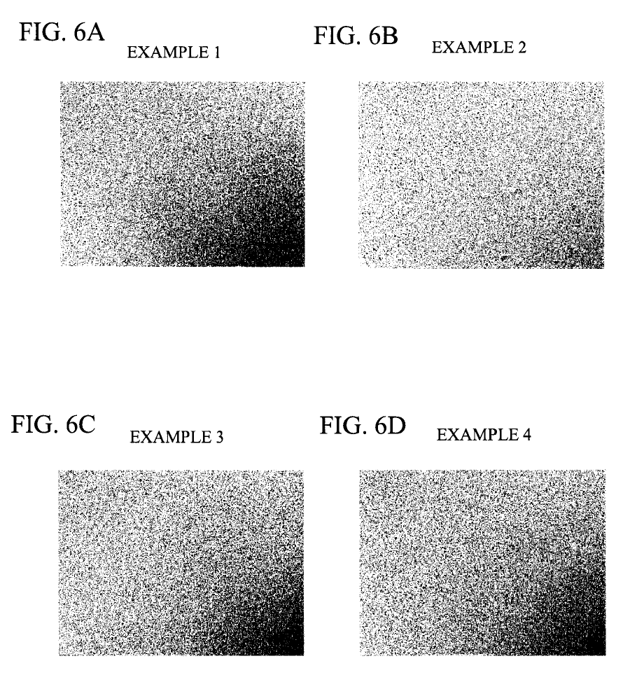

In contrast, in the examples 1 to 11, the InAlAsP layer having the thickness of 1.0 μm or more was grown at a temperature higher than that of the comparative examples 1 and 2. As illustrated in FIG. 6A to FIG. 8C, in the examples 1 to 11, convexo-concave was not observed on the surface of the InAlAsP layer.

As is obvious from the results of the examples 1 to 11, it may be understood that the convexo-concave of the surface is restrained when the growth temperature of the InAlAsP is 680 degrees C. or more even if the thickness of the InAlAsP is 1.0 μm or more.

As is shown in the examples 1 to 11, the convexo-concave was not observed on the surface despite the thickness of 1.0 μm or more. It is thought a relation between a miscibility gap range and the growth temperature causes the results.

That is, growth of an uneven mixed crystal in semiconductor may cause the convexo-concave of the surface. The condition of the comparative examples 1 and 2 is within a miscibility gap in which the uneven mixed crystal tends to grow. When the thickness is large, the convexo-concave appears on the surface because of the uneven mixed crystal. On the other hand, as shown in the examples 1 to 11, an even mixed crystal is grown, because the miscibility gap range is reduced under a condition of high growth temperature. Accordingly, the convexo-concave on the surface is reduced.

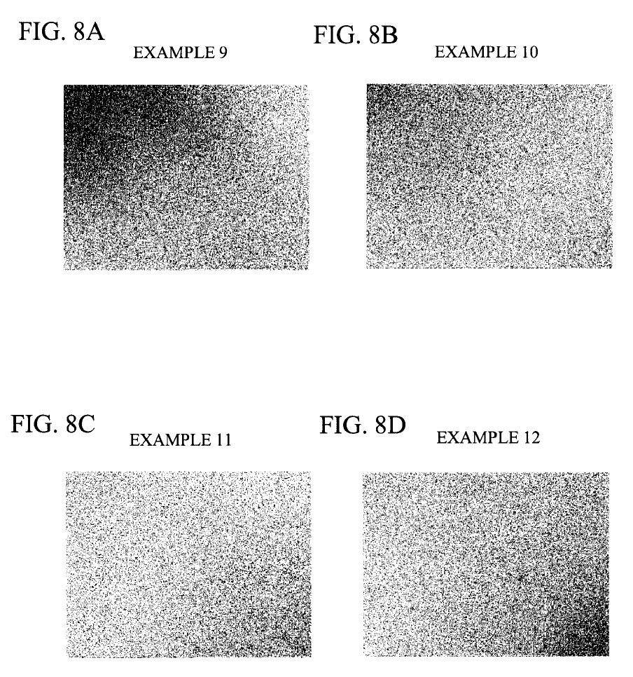

In the examples 1 to 11, the growth of the InAlAsP is reviewed. As shown in the example 12, the effect of the present invention was confirmed with respect to the growth of the InAlGaAsP. As illustrated in FIG. 8D, in the example 12, the convexo-concave on the surface is reduced. The convexo-concave was reduced when the composition ratio “X” of Ga in group 3 (InAlGa) was equal to 0.08. Therefore, the present invention may be effective when the growth temperature is 680 degrees C. or more and the thickness is 1.0 μm or more with respect to the InAlGaAsP (the composition ratio “x” of Ga is 0≦x≦0.08).

It is feared that the surface gets rough because of the volatilization of phosphorus, because the temperature is relatively high in the examples 1 to 12. However, as is obvious from the examples 1 to 12, the roughness of the surface caused by the volatilization of phosphorus was not observed. The examples revealed this observation for the first time. This may be because phosphorus did not volatilize at a high temperature because a bonding between aluminum and phosphorus is relatively strong. However, it is preferable that the growth temperature of 750 degrees C. or less may be adopted with respect to a semiconductor device needing a high quality surface, because thermal energy may cause volatilization of phosphorus at the growth temperature of 750 degrees C. or more.

The high quality InAlAsP layer and the high quality InGaAlAsP layer are formed when the growth temperature is 680 degrees C. or more even if the growth thickness is 1.0 μm or more.

The present invention is not limited to the specifically described embodiments and variations but other embodiments and variations may be made without departing from the scope of the claimed invention.

What is claimed is:

1. A method for manufacturing a semiconductor device comprising
growing an InAlGaAsP layer having a thickness of 1.0 μm or more on a surface of an InP semiconductor layer at a growth temperature of 680 degrees C. or more,
a composition ratio “X” of Ga in InAlGa of the InAlGaAsP being 0≦X≦0.08.

2. The method as claimed in claim 1 further comprising growing an optical waveguide layer on the InAlGaAs layer.

3. The method as claimed in claim 2, wherein a layer having a thickness of 1 μm or more is provided between the optical waveguide layer and the InAlGaAsP layer.

4. The method as claimed in claim 1, wherein the growth temperature of the InAlGaAsP layer is 700 degrees C. or more.

5. The method as claimed in claim 1, wherein the growth temperature of the InAlGaAsP layer is 730 degrees C. or more.

6. The method as claimed in claim 1, wherein the growth temperature of the InAlGaAsP layer is 750 degrees C. or less.

7. The method as claimed in claim 1, wherein:
the composition ratio “X” of Ga in the InAlGaAsP is zero; and
a composition ratio “Y” of Al in InAl is 0.09≦Y≦0.37.

8. The method as claimed in claim 1, wherein:
the composition ratio “X” of Ga in the InAlGaAsP is zero; and
a composition ratio “Z” of P in AsP is 0.20≦Z≦0.80.

9. The method as claimed in claim 1 wherein the InP semiconductor layer has a face of {100} plus minus 0.08 degrees.

10. The method as claimed in claim 2 further comprising providing a heater on the optical waveguide layer.

11. The method as claimed in claim 1, wherein:
the InP semiconductor layer is grown on a semiconductor substrate; and
an etch pit density of a surface of the semiconductor substrate is 2000/cm² or less.
